(19) United States
(12) Patent Application Publication
(10) Pub. No.: US 2003/0118064 A1
(43) Pub. Date: Jun. 26, 2003

(54) Laser and method for production thereof

(75) Inventors: Xinwei Zhao, Wako-shi (JP); Shuji Komuro, Tsurugashima-shi (JP); Hideo Isshiki, Wako-shi (JP); Yoshinobu Aoyagi, Wako-shi (JP); Takuo Sugano, Wako-shi (JP)

Correspondence Address: BIRCH STEWART KOLASCH & BIRCH, PO BOX 747, FALLS CHURCH, VA, 22040-0747, US

(73) Assignee: Riken

(21) Appl. No.: 10/309,192

(22) Filed: Dec. 4, 2002

Related U.S. Application Data
(63) Continuation of application No. 09/472,894, filed on Dec. 28, 1999, now abandoned.

(30) Foreign Application Priority Data
Dec. 28, 1998 (JP) 10-372032

(51) Int. Cl. H01S 3/14; H01S 5/00

(52) U.S. Cl. 372/39; 372/43

(57) ABSTRACT

The invention provides a laser and a method for the production thereof by which it is possible to fabricate a device on a Si substrate, and to fabricate further an optical device such as an optical memory on the Si substrate. The laser has an Er-doped nano-ultrafine crystalline Si waveguide formed on the Si substrate wherein the Er-doped nano-ultrafine crystalline Si layer is co-doped with oxygen to result in a structure in which Er ion is surrounded by at least one or more oxygen atom(s).

### BACKGROUND OF THE INVENTION

1. Field of the Invention

The present invention relates to a laser and a method for the production thereof, and more particularly to a laser and a method for the production thereof wherein a silicon (Si) material doped with a rare earth element, i.e., an Er-doped Si material is used, especially to a laser and a method for the production thereof by which it is possible to produce an optical device such as an optical memory on a Si substrate.

2. Description of the Related Art

The present applicant has filed a patent application, Japanese Patent Application No. 8-132846 entitled “Si material doped with a rare earth element and method for production thereof” (filed on Apr. 30, 1996, Japanese Patent Laid-Open No. 9-295891) which is applicable to an optical device.

In Japanese Patent Application No. 8-132846 entitled “Si material doped with a rare earth element and method for production thereof”, it has been disclosed that a Si material doped with a rare earth element is fabricated by doping Si prepared in ultrafine crystal having an average particle diameter of, for example, around 3 nm, in other words, in nm-order (hereinafter referred to as “nano-ultrafine crystalline Si”) with a rare earth element such as erbium (Er), whereby it is possible to develop visible emission derived from the nano-ultrafine crystalline Si as well as to develop infrared emission and visible emission derived from the rare earth element.

Furthermore, it has been disclosed in the Japanese Patent Application No. 8-132846 entitled “Si material doped with a rare earth element and method for production thereof” that a rare earth element is ion-implanted in high-purity amorphous Si thin film, whereby a Si material doped with the rare earth element containing atom of the rare earth element as its nucleus can be produced, or that a Si material doped with a rare earth material can be produced directly from a Si target to which has been applied a rare earth element by the use of laser ablation manner.

### OBJECTS AND SUMMARY OF THE INVENTION

An object of the present invention is to provide a laser and a method for the production thereof by which it becomes possible to fabricate a device on a Si substrate, more specifically, it becomes possible to fabricate an optical device such as optical memory on a Si material, and which is obtained by developing further Japanese Patent Application No. 8-132846 entitled “Si material doped with a rare earth element and method for production thereof” filed by the present applicant.

In order to attain the above described object, the laser and the method for the production thereof according to the present invention has been made by directing the applicant's attention to the fact that a Si material doped with a rare earth element exhibits intensive light emission at room temperature.

For example, a Si thin film doped with a rare earth element being a nano-ultrafine crystalline Si doped with Er as a rare earth element fabricated by means of laser ablation (hereinafter referred to as “Er-doped nano-ultrafine crystalline Si”) thin film exhibits intensive Er-light emission at room temperature.

The reason why the Er-doped nano-ultrafine crystalline Si thin film exhibits such intensive Er-light emission at room temperature may be considered to reside in a cause due to changes in energy band structure derived from the resulting nano-ultrafine crystalline Si, a result of oxygen co-doping and the like.

According to laser ablation, Er can be applied to nano-ultrafine crystalline Si in a higher density than solid solubility of Er, and it seems to be a factor for exhibiting intensive Er-light emission at room temperature.

The present invention is constituted in such that an Er-doped nano-ultrafine crystalline Si optical waveguide is formed on a Si substrate to produce laser wherein it is adapted to obtain stimulated light emission of Er at room temperature.

More specifically, the laser according to the present invention relates to a laser having an Er-doped nano-ultrafine crystalline Si waveguide formed on a Si substrate wherein the Er-doped nano-ultrafine crystalline Si layer is co-doped with oxygen, so that the resulting structure is such that Er ion is surrounded by at least one or more oxygen atom(s).

Furthermore, the laser according to the present invention relates to a laser having an oxide film layer formed on a Si substrate and an optical waveguide made of an Er-doped nano-ultrafine crystalline Si film layer formed in the aforesaid oxide film wherein the Er-doped nano-ultrafine crystalline Si layer is co-doped with oxygen, so that the resulting structure is such that Er ion is surrounded by at least one or more oxygen atom(s).

Moreover, the present invention relates to a laser having an optical waveguide containing p-n junction of an Er-doped nano-ultrafine crystalline Si wherein the Er-doped nano-ultrafine crystalline Si layer is co-doped with oxygen, so that the resulting structure is such that Er ion is surrounded by at least one or more oxygen atom(s).

In the laser according to the present invention, the number of oxygen atoms surrounding Er ion may be six.

The production of a laser according to the present invention relates to a production of a laser wherein a striped structure of an Er-doped nano-ultrafine crystalline Si film layer is fabricated on an oxide film layer formed on a Si substrate, an oxide film layer is deposited on the striped structure of the aforesaid Er-doped nano-ultrafine crystalline Si film layer, and cleavage is applied to the above described striped structure after the deposition of the oxide film layer on the aforesaid striped structure was completed to define an optical waveguide wherein the Er-doped nano-ultrafine crystalline Si layer is co-doped with oxygen, so that the resulting structure is such that Er ion is surrounded by at least one or more oxygen atom(s).

In the method for production of a laser according to the present invention, a striped structure of the Er-doped nano-ultrafine crystalline Si film layer may be fabricated on the oxide film layer formed on the Si substrate by utilizing laser ablation and lift-off method.

Moreover, in the method for production of a laser according to the present invention, the number of oxygen atoms surrounding Er ion may be six.

### BRIEF DESCRIPTION OF THE DRAWINGS

The present invention will become more fully understood from the detailed description given hereinafter and the accompanying drawings which are given by way of illustration only, and thus are not limitative of the present invention, and wherein:

FIG. 1 is an explanatory view illustrating conceptually a manner for fabricating an Er-doped nano-ultrafine crystalline Si thin film on a Si(100) substrate in accordance with laser ablation;

FIG. 2 is a graphical representation showing changes in intensity of light emission versus temperature changes in respect of an Er-doped nano-ultrafine crystalline Si thin film;

FIG. 3 is an explanatory view, in conceptual constitution, showing a laser constituted by an optical waveguide of an Er-doped nano-ultrafine crystalline Si thin film defined in accordance with a manner of laser ablation;

FIG. 4 is a graphical representation showing excitation intensity dependence of Er light emission from the optical waveguide in the case where a length of the optical waveguide 110 shown in FIG. 3 is 6 mm;

FIG. 5 is an explanatory view, in conceptual constitution, showing an electric current injection laser;

FIG. 6 is an explanatory view, in conceptual constitution, showing a distribution feedback laser (DFB laser);

FIG. 7 is an explanatory view, in conceptual constitution, showing a surface light emission laser;

FIG. 8 is an explanatory view, in conceptual constitution, showing an example in the case where a LSI and an optical device are formed on the same Si substrate;

FIG. 9 is a graphical representation showing light emission characteristics of a Nd-doped nano-ultrafine crystalline Si which is prepared by doping the nano-ultrafine crystalline Si with Nd₂O₃;

FIG. 10 is a graphical representation in which a pressure of oxygen introduced into a vacuum chamber in case of laser ablation is plotted as abscissa and intensity of light emission from Er as ordinate, and which indicates the intensity of light emission of a material immediately after ablation (as-abl.) as well as that of a material treated thermally (600/3); and

FIG. 11 is a graphical representation showing output characteristics of a DFB laser.

### DETAILED DESCRIPTION OF THE PREFERRED EMBODIMENTS

An example of preferred embodiments of a laser and a method for the production thereof according to the present invention will be described in detail hereinafter by referring to the accompanying drawings.

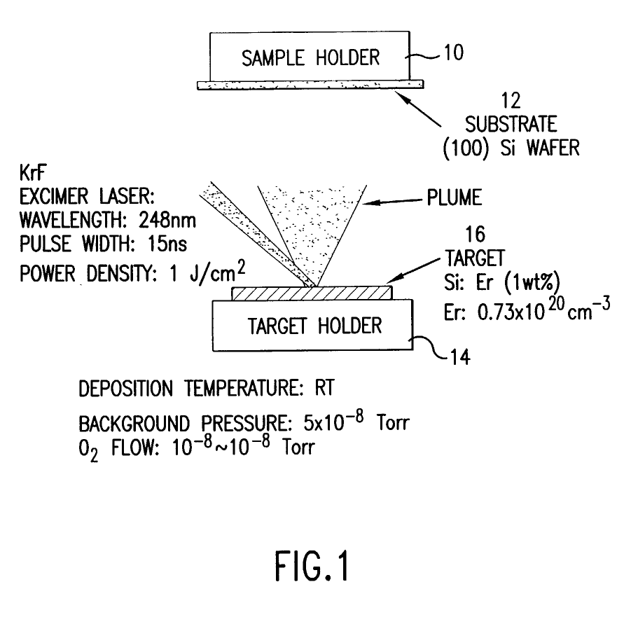

FIG. 1 shows conceptually a manner for fabricating an Er-doped nano-ultrafine crystalline Si thin film on a Si (100) substrate 12 composed of a (100) Si wafer supported by a sample holder 10 (hereinafter referred simply to as “Si substrate”) in accordance with laser ablation.

Namely, a material Si: Er 16 a doping concentration in Er of which is 1 wt % is placed on a target holder 14 as its target. In this case, density of Er is 0.73×10²⁰ cm⁻³.

When KrF excimer laser having 248 nm wavelength, 15 ns pulse width, and 1 J/cm² power density is applied to the Si: Er 16 being its target, the Si: Er is decomposed to produce plume consisting of ions, atoms, radicals and the like of the Si: Er, whereby an Er-doped nano-ultrafine crystalline Si thin film is formed on the Si substrate 12.

According to the above described laser ablation, Er can be applied to such nano-ultrafine crystalline Si at a density higher than the solubility of Er.

The aforesaid laser ablation was conducted in a vacuum chamber (not shown) wherein the deposition temperature was room temperature (RT), and the degree of vacuum (background pressure) was 5×10⁻⁸ Torr.

In this case, when oxygen (O₂) is allowed to flow in the vacuum chamber at 10⁻⁶ to 10⁻¹ Torr to cause oxygen (O₂) flow, whereby the oxygen is applied to the Er-doped nano-ultrafine crystalline Si, then, intensity of light emission of Er increases, so that depletion of Er-light emission caused by temperature increasing can be prevented.

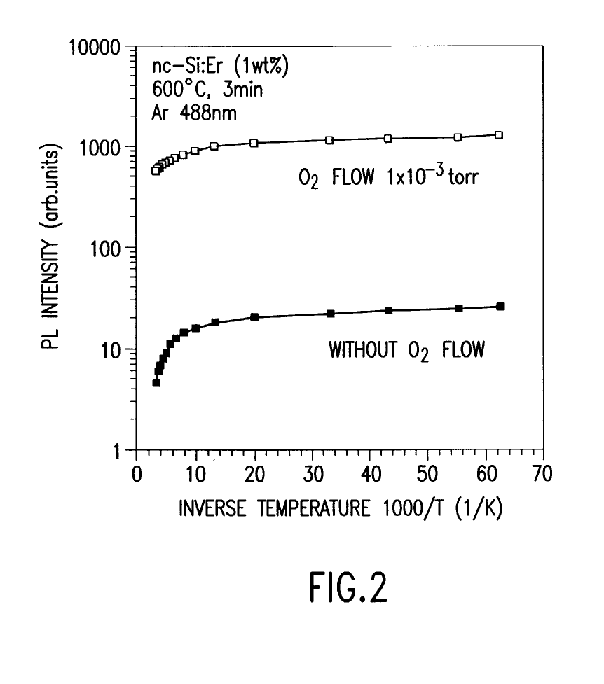

For instance, it is represented in FIG. 2 that intensity of Er-light emission increases as a result of application of oxygen, whereby it is prevented from attenuation of light emission at room temperature.

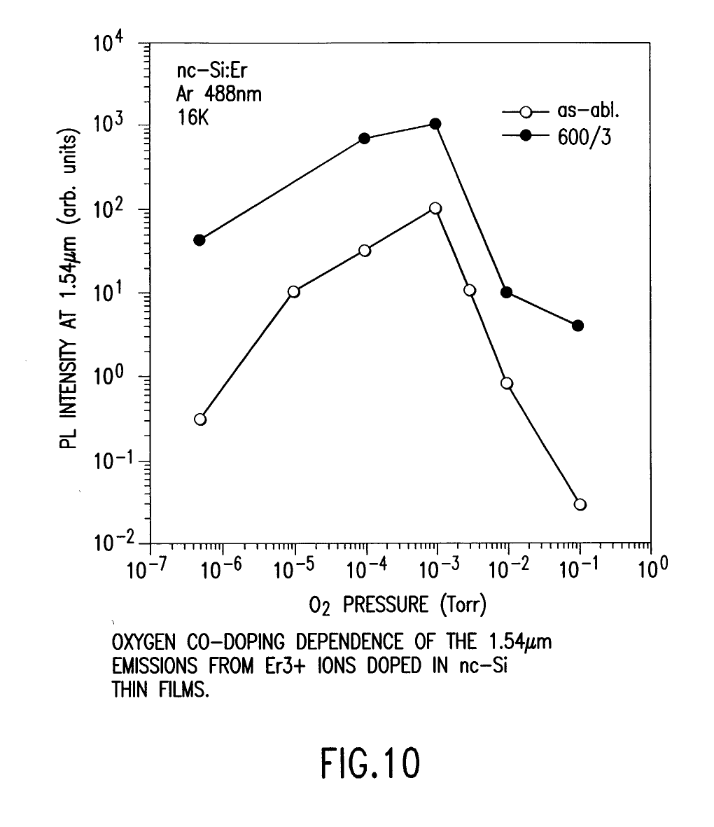

FIG. 10 is a graphical representation in which a pressure of oxygen introduced into a vacuum chamber in case of laser ablation is plotted as abscissa and intensity of light emission from Er as ordinate. In FIG. 10, it is to be noted that the graph indicates both of the intensity of light emission of a material immediately after ablation (as-abl.) and that of a material treated thermally (600/3).

In an Er-doped nano-ultrafine crystalline Si co-doped with oxygen, the oxygen reacts with Er ion and radical to form center of light emission.

However, excessive application of oxygen causes also oxidation of nano-ultrafine crystals of Si, so that the material itself is transelemented, whereby Er-light emission attenuates also. In this respect, according to experiments by the present applicant, it has been confirmed that effective light emission is achieved by a structure wherein an Er ion is surrounded by at least one or more oxygen atom(s), preferably six oxygen atoms.

Accordingly, in order to produce oxygen co-doped, Er-doped nano-ultrafine crystalline Si exhibiting intensive intensity of light emission as a result of achieving the structure wherein an Er ion is surrounded by at least one or more oxygen atom(s), preferably six oxygen atoms, it is most suitable that oxygen is allowed to flow in the vacuum chamber at 10⁻³ Torr to cause oxygen flow, whereby the oxygen is applied to the Er-doped nano-ultrafine crystalline Si as shown in FIG. 10.

Furthermore, the Er-doped nano-ultrafine crystalline Si (Si: Er) thin film formed as described above is subjected to annealing in nitrogen (N₂) atmosphere at a temperature of 400 to 900° C. for only 1 to 80 minutes.

The Er density in the Er-doped nano-ultrafine crystalline Si thin film thus obtained was 1×10²⁰ cm⁻³.

FIG. 2 is a graphical representation showing changes in intensity of light emission versus temperature changes in respect of the Er-doped nano-ultrafine crystalline Si thin film prepared in accordance with the manner as described above wherein inverse temperatures 1000/T (1/K) are plotted as abscissa and intensity of light emission (PL intensity (arb. unit)) as ordinate.

In the graph shown in FIG. 2, experimental results in respect of the Er-doped nano-ultrafine crystalline Si thin film (nc-Si: Er (1 wt %)) which has been annealed at 600° C. temperature for only 3 minutes are shown.

As is apparent from the graphical representation of FIG. 2, absolute intensity of light emission increases and at the same time, attenuation of Er-light emission in temperature rise can be prevented in the case when O₂ is supplied at 1×10⁻³ Torr at the time of conducting laser ablation as compared with the case where no O₂ is supplied at the time of applying laser ablation.

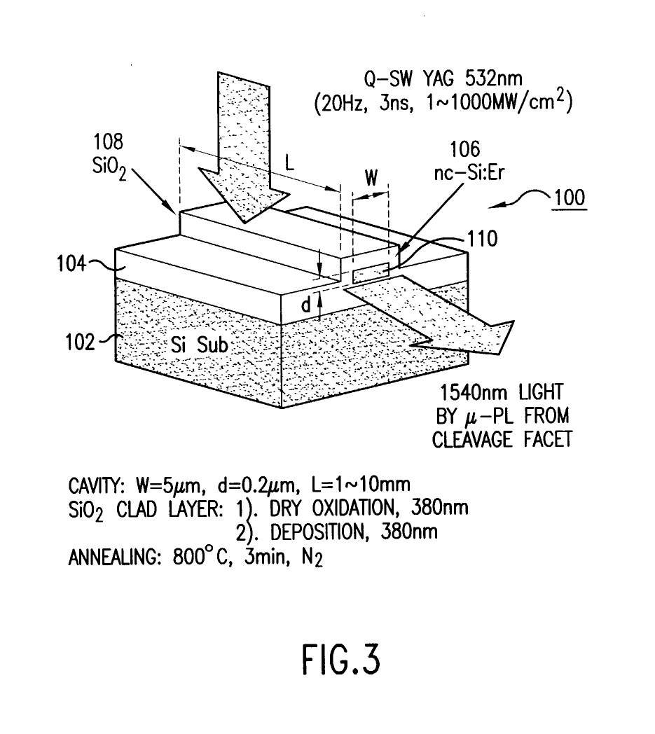

FIG. 3 shows a laser constituted by an optical waveguide of an Er-doped nano-ultrafine crystalline Si (nc-Si: Er) thin film defined in accordance with the above described manner of laser ablation.

More specifically, a laser 100 is obtained in accordance with such manner that an oxide film (SiO₂) 104 is formed on the surface of a Si (100) substrate 102, a striped structure of an Er-doped nano-ultrafine crystalline Si thin film (nc-Si: Er) 106 is fabricated on the oxide film 104 by utilizing laser ablation and a lift-off method, and further an oxide film (SiO₂) 108 is deposited thereon, thereafter cleavage is applied to the resulting material to prepare an optical waveguide 110.

In other words, the optical waveguide 110 is prepared by deposition of the Er-doped nano-ultrafine crystalline Si thin film, patterning, and oxide film covering thereof.

In this case, a concentration of doped Er is 1 wt % in the Er-doped nano-ultrafine crystalline Si thin film 106, while a dimension of the optical waveguide 110 is such that, for example, a width (W) is 5 μm, a thickness (d) is 0.2 μm, and a length is 1 to 10 mm. Furthermore, a thickness of both the oxide films 104 and 108 of SiO₂ are 380 nm, respectively.

In case of preparing the optical waveguide 110, the material was annealed in nitrogen atmosphere at 800° C. for only 3 minutes.

When Q-switched YAG (Q-SWYAG) laser having 532 nm wavelength, 20 Hz frequency, 3 ns pulse width, 1 to 1000 MW/cm² excitation power density is applied as excitation laser to the optical waveguide constituted as described above, stimulated light emission of Er of which the wavelength is 1540 nm (1.54 μm) is obtained from its cleavage facet, so that it was confirmed that the optical waveguide 110 functions as a laser.

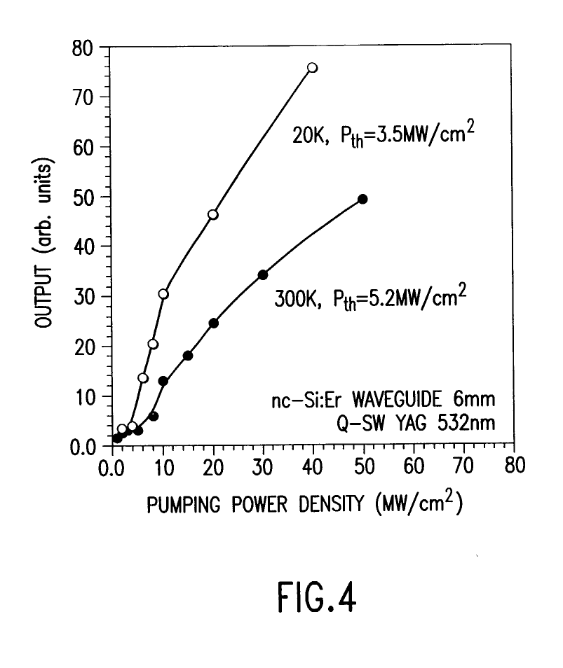

FIG. 4 shows excitation intensity dependence of Er-light emission from the optical waveguide 110 in the case where a length of the optical waveguide 110 shown in FIG. 3 is 6 mm wherein the excitation (pumping) power densities (MW/cm²) of Q-switched YAG laser are plotted as abscissa and output values of the stimulated light emission of Er having 1540 nm wavelength from the cleavage facet of the optical waveguide 110 as ordinate.

As indicated in FIG. 4, clear super-linear characteristics are observed in case of low pumping power density of the Q-switched YAG laser, i.e., low excitation, and a threshold value (Pₜₕ) of light emission is observed. The threshold value is 3.5 MW/cm² in the case when a temperature is 20K, while 5.2 MW/cm² in the case when a temperature is 300K, and the threshold value increases at room temperature in comparison with a case of a low temperature.

On the other hand, when a pumping power density of the Q-switched YAG laser is high, i.e., in high excitation, saturation of light emission is observed.

The reason why such saturation of light emission occurs may be considered in such that either excitation itself of Er ion becomes saturated or it is due to a device structure.

Moreover, from such fact that life time of Er-light emission decreases remarkably with increase of a pumping power density of the Q-switched YAG laser in the vicinity of the threshold value, it may be concluded that stimulated light emission of Er occurs. Therefore, it is understood that a resonator is formed with both cleavage facets, whereby the optical waveguide 110 functions as a laser.

Consequently, when reflectivity is increased by coating both the cleavage facets, an efficient resonator is formed with both the cleavage facets, so that more improved functions can be obtained as a laser of the optical waveguide 110.

When a length of the optical waveguide 110 shown in FIG. 3 is reduced to 3 mm, the number of Er is smaller than that in case where a length of the optical waveguide 110 is 6 mm, so that a threshold value becomes 20 MW/cm² at temperature of 20K, resulting in a higher threshold value than that in case where a length of the optical waveguide 110 is 6 mm.

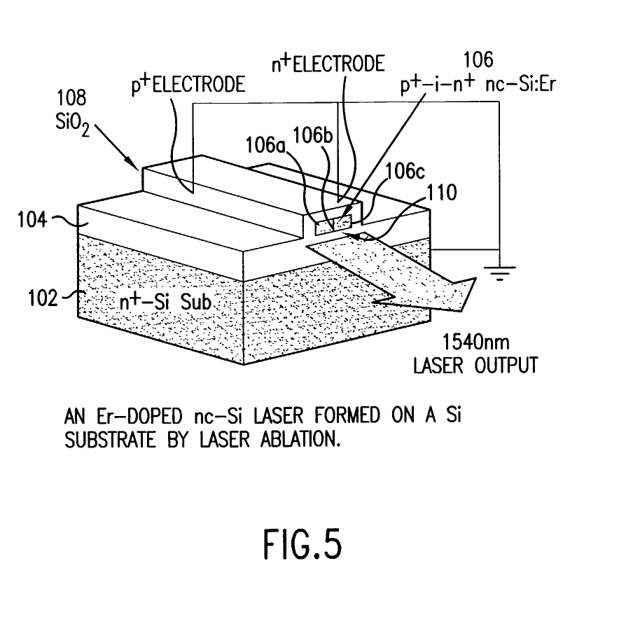

Furthermore, FIG. 5 shows an electric current injection laser which is produced in such that a p-type Er-doped nano-ultrafine crystalline Si thin film 106a is formed in an optical waveguide 110 along the longitudinal direction thereof, an intrinsic Er-doped nano-ultrafine crystalline Si thin film 106b is formed along the p-type Er-doped nano-ultrafine crystalline Si thin film 106a, and a n-type Er-doped nano-ultrafine crystalline Si thin film 106c is formed along the intrinsic Er-doped nano-ultrafine crystalline Si thin film 106b.

In the optical waveguide 110 shown in FIG. 5, when electric current is applied as shown in FIG. 5, an electric current injection laser can be formed.

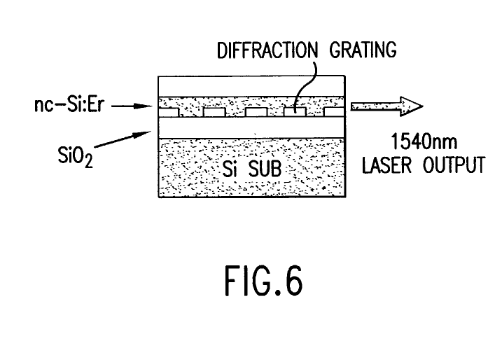

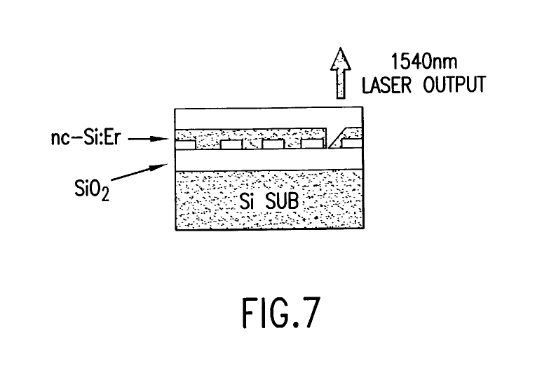

Moreover, when it is arranged as shown in FIG. 6 in such that a diffraction grating is disposed in every ¼ wavelength of 1.54 μm wavelength, a distribution feedback (DFB) laser can be constituted. Further, a surface light-emitting laser can be constituted by arranging in such that light is output through the surface thereof as shown in FIG. 7.

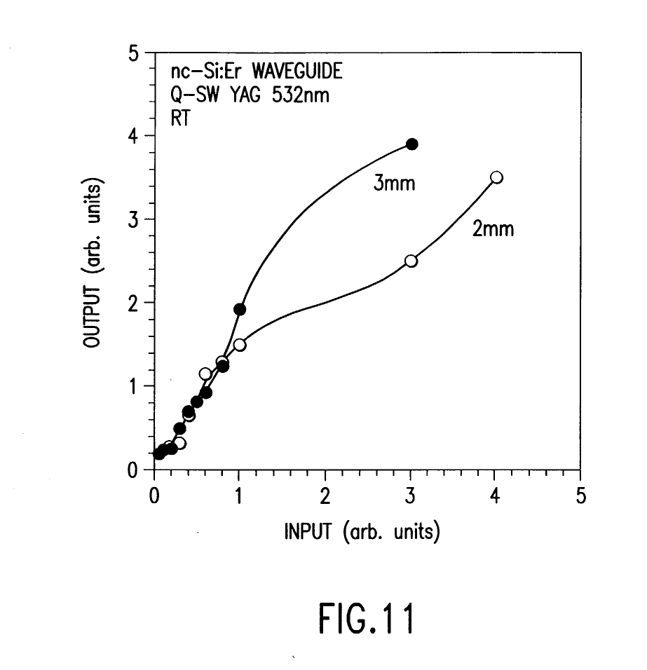

Referring to FIG. 11, a graph indicating output characteristics of a DFB laser is represented.

More specifically, the threshold value decreased for every DFB laser. In other words, since a reflectivity is higher in distribution feedback type laser, there is an increased gain. Notwithstanding the above description, a comparatively long resonator exhibits characteristics of being more hardly saturated.

According to the present applicant's experiment, it has been confirmed that an improvement in output can be achieved by providing a laser array wherein several tens of waveguides are arranged transversely.

In addition, since Er-doped nano-ultrafine crystalline Si emits light having 1.54 μm wavelength as described above, it becomes possible to integrate together an electronic circuit with an optical circuit on the same Si substrate by the use of the Er-doped nano-ultrafine crystalline Si.

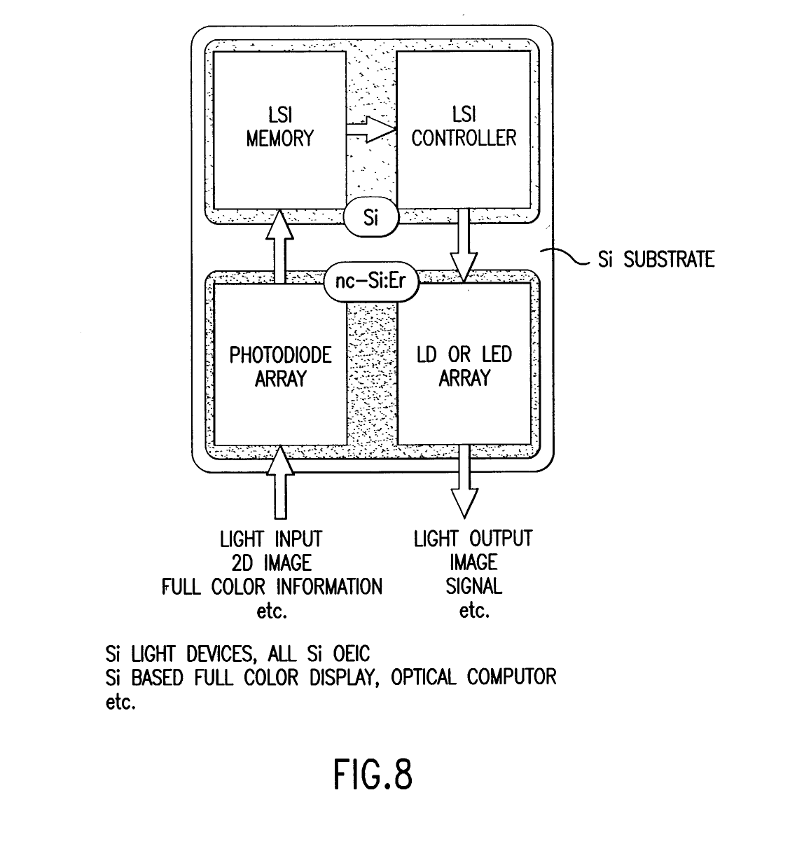

Specifically, as shown in FIG. 8, it becomes possible to produce a photodiode array, a LD or a LED array with the use of an Er-doped nano-ultrafine crystalline Si (nc-Si: Er) in addition to a LSI memory or a LSI controller by the use of Si on the same Si substrate.

In the example shown in FIG. 8, it is constituted in such that optical having information is input from the photodiode array, while the processed optical information is output from the LD or LED array.

Although the case where a nano-ultrafine crystalline Si is doped with Er as a rare earth element has been described above, such rare earth element is, of course, not limited to Er, but the other rare earth elements are also applicable. For example, a Nd-doped nano-ultrafine crystalline Si prepared by doping a nano-ultrafine crystalline Si with neodymium (Nd) as a rare earth element emits light also.

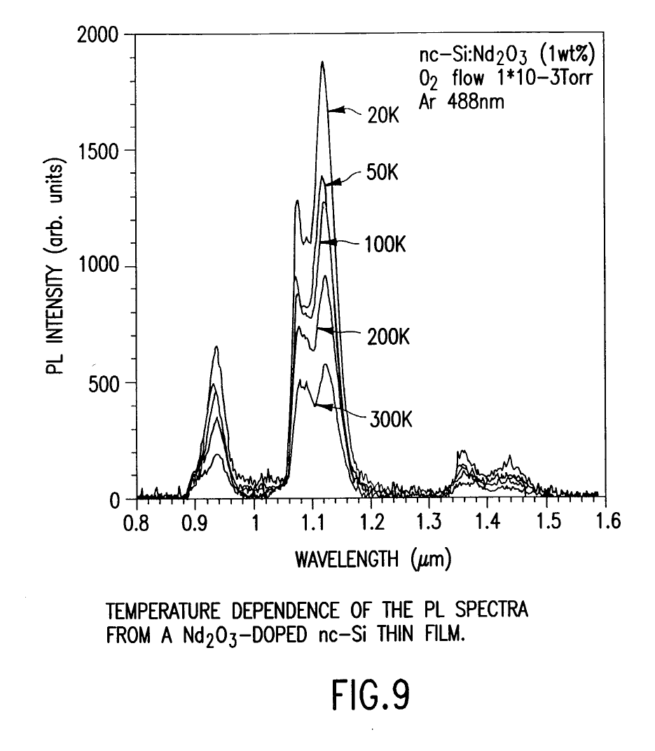

FIG. 9 is a graph showing light emission characteristics of a Nd-doped nano-ultrafine crystalline Si which is prepared by doping the nano-ultrafine crystalline Si with Nd₂O₃ wherein the most intensive light emission is observed at 1.06 μm wavelength.

Accordingly, it is possible to produce a laser which oscillates at 1.06 μm wavelength from the Nd-doped nano-ultrafine crystalline Si as in the above described case of the Er-doped nano-ultrafine crystalline Si.

Moreover, a Yb-doped nano-ultrafine crystalline Si prepared by doping a nano-ultrafine crystalline Si with Yb as a rare earth element emits light at 1.0 μm wavelength. A Ho-doped nano-ultrafine crystalline Si prepared by doping a nano-ultrafine crystalline Si with Ho as a rare earth element emits light at 1.13 μm wavelength. A Tb-doped nano-ultrafine crystalline Si prepared by doping a nano-ultrafine crystalline Si with Tb as a rare earth element emits light in a wavelength region of visible light. An Eu-doped nano-ultrafine crystalline Si prepared by doping a nano-ultrafine crystalline Si with Eu as a rare earth element emits light in a wavelength region extending from visible light to near-infrared light. Therefore, a laser or an optical device which oscillates at a desired wavelength can be constituted by selecting suitably a rare earth element with which a nano-ultrafine crystalline Si to be doped.

Since the present invention has been constituted as described above, it is possible to provide a laser and a method for the production thereof by which such an excellent advantage that an optical device can be manufactured on a Si substrate is achieved.

It will be appreciated by those of ordinary skill in the art that the present invention can be embodied in other specific forms without departing from the spirit or essential characteristics thereof.

The presently disclosed embodiments are therefore considered in all respects to be illustrated and not restrictive. The scope of the invention is indicated by the appended claims rather than the foregoing description, and all changes that come within the meaning and range of equivalents thereof are intended to be embraced therein.

The entire disclosure of Japanese Patent Application No. 10-372032 filed on Dec. 28, 1999 including specification, claims, drawings and summary are incorporated herein by reference in its entirety.

What is claimed is:

1. A laser having an Er-doped nano-ultrafine crystalline Si waveguide formed on a Si substrate, wherein:
said Er-doped nano-ultrafine crystalline Si layer is co-doped with oxygen, so that the resulting structure is such that Er ion is surrounded by at least one or more oxygen atom(s).

2. A laser having an oxide film layer formed on a Si substrate and an optical waveguide made of an Er-doped nano-ultrafine crystalline Si film layer formed in said oxide film, wherein:
said Er-doped nano-ultrafine crystalline Si layer is co-doped with oxygen, so that the resulting structure is such that Er ion is surrounded by at least one or more oxygen atom(s).

3. A laser having a waveguide containing p-n junction of an Er-doped nano-ultrafine crystalline Si, wherein:
said Er-doped nano-ultrafine crystalline Si layer is co-doped with oxygen, so that the resulting structure is such that Er ion is surrounded by at least one or more oxygen atom(s).

4. A laser as claimed in any one of claims 1, 2, and 3, wherein:
said resulting structure is such that the Er ion is surrounded by six oxygen atoms.

5. A method for the production of a laser in which:
a striped structure of an Er-doped nano-ultrafine crystalline Si film layer is fabricated on an oxide film layer formed on a Si substrate,
an oxide film layer is deposited on said striped structure of the Er-doped nano-ultrafine crystalline Si film layer, and
cleavage is applied to said striped structure after the deposition of the oxide film layer on said striped structure was completed to define an optical waveguide, wherein:
said Er-doped nano-ultrafine crystalline Si layer is co-doped with oxygen, so that the resulting structure is such that Er ion is surrounded by at least one or more oxygen atom(s).

6. A method for the production of a laser as claimed in claim 5, wherein:
the striped structure of said Er-doped nano-ultrafine crystalline Si film layer is fabricated on an oxide film layer formed on a Si substrate by utilizing laser ablation and lift-off manner.

7. A method for the production of a laser as claimed in any one of claims 5 and 6, wherein:
said resulting structure is such that the Er ion is surrounded by six oxygen atoms.
